(19) United States
(12) Patent Application Publication
(10) Pub. No.: US 2026/0293363 A1
(43) Pub. Date: Sep. 24, 2026

(54) INNOVATIVE PHOTOMOBILE POLYMER, METHOD FOR PREPARING SAID PHOTOMOBILE POLYMER WITHOUT RUBBING, AND HANDLING DEVICE FOR A PHOTOVOLTAIC PANEL

(71) Applicants: CONSIGLIO NAZIONALE DELLE RICERCHE, Roma (IT); ENEA - Agenzia nazionale per le nuove tecnologie, l’energia e lo sviluppo economico sostenibile, Roma (IT)

(72) Inventors: Domenico SAGNELLI, Caserta (IT); Ambra VESTRI, Pistoia (IT); Lucia PETTI, Napoli (IT); Fulvia VILLANI, Roma (IT); Tiziana POLICHETTI, Roma (IT); Giuseppe NENNA, Roma (IT); Fausta LOFFREDO, Roma (IT); Anna DE GIROLAMO DEL MAURO, Roma (IT)

(21) Appl. No.: 19/162,502

(22) PCT Filed: Mar. 12, 2024
(86) PCT No.: PCT/IB2024/052376

§ 371 Date: Sep. 5, 2025

(30) Foreign Application Priority Data
Mar. 14, 2023 (IT) 102023000004743

(51) Int. Cl. H10F 71/00; B82Y 30/00; C09K 19/04; C09K 19/56; H02S 20/32; H02S 40/22

(52) U.S. Cl. CPC H10F 71/134; B82Y 30/00; C09K 19/04; C09K 19/56; H02S 20/32; H02S 40/22; C09K 2019/0448

(57) ABSTRACT

A process for the preparation of a doped photomobile polymer characterised by having no rubbing stage is described, as well as the photomobile polymer obtained by said process and a handling device for moving a single solar cell to a photovoltaic panel comprising said photomobile polymer.

### BACKGROUND ART

The inventors of the present invention have previously synthesised photopolymers doped with ZnO nanoparticles in a concentration of 6%. The process involved rubbing the substrate so that the liquid crystal molecules took on an orientational order (Sagnelli D. et al., Photo-Responsivity Improvement of Photo-Mobile Polymers Actuators Based on a Novel LCs/Azobenzene Copolymer and ZnO Nanoparticles Network, Nanomaterials 2021, 11, 3320. https://doi.org/10.3390/nano11123320).

### Technical Problem

In the preparation of photomobile polymers, the methods known in the state of the art typically require the substrate to undergo a “mechanical rubbing” process in order to provide spatial orientation patterns for the molecules interacting with these patterns. These methods require processing steps that are time-consuming and costly and often lead to undesirable variations in the alignment of the liquid crystal molecules, resulting in inconsistent performance of the liquid crystal photopolymer. A further technical problem that the inventors have noticed is that linked to the use of liquid crystal photopolymer in 3D printing applications in which the needs of preparing and/or creating the rubbing layer make this processing step difficult to use. Further, the inventors realised that the optimisation of light harvesting by both flat and concentrating photovoltaic systems requires the development of specific trackers, which, although sufficiently effective in terms of solar cell operation, are not only complex in design but also energy-intensive and expensive.

In particular, part of the energy collected is required for their operation and their cost has a significant impact on the overall system.

Further, the inventors also noted that the use of increasingly sophisticated optics points towards the implementation of different types of Concentrating Solar Power (CSP) plants. Their advantage over wind turbines or photovoltaic plants is the easy implementation with energy storage systems obtained from an electrical storage device and thus the generation of energy that can be channeled.

For the development of concentration systems, the use of the aforementioned trackers that enable the correct tracking of the sun is essential. The use of trackers is essential for both flat and concentrating photovoltaic systems and also for concentrating solar thermal power systems.

Some types of trackers are known especially for handling mirrors, CPCs (compound parabolic collectors), lenses, photovoltaic panels, etc.

There are two main types of solar tracking systems categorised according to degrees of freedom and movement: the single-axis solar tracking system and the dual-axis solar tracking system. Within these categories, further sub-types can be distinguished: north-south single-axis tracking, azimuth tracking, horizontal tracking, north-south axis tracking, dual-axis tracking, altazimuth tracking, azimuth and elevation tracking, etc.

Within this technological framework, the inventors have perceived the need to identify a further route running parallel to the exploitation of concentrated sunlight. The state of the art presents concentrated systems with handling devices made in different configurations, but all based on a mechanical technology that usually uses electrical energy, partly impacting the energy collected by the system to be handled. The inventors found that it was possible to create an innovative handling device not based on mechanical technology but implemented through the use of photomobile polymers by predicting their bending (not their pure elongation). It is relevant to note that with this proposal, the tracking system will be able to operate without using the energy produced by the plant, because it does not have a mechanical handling system, but directly from solar radiation.

It is interesting to note that the inventors surprisingly verified that the specific doping of a liquid crystal polymer with appropriately selected nanoparticles at a specific predetermined concentration allows for a process of spatial self-organisation in which the liquid crystal molecules are aligned in a specific direction without the need for the substrate to be pre-treated by a rubbing stage.

Importantly, the inventors found that this alignment related to spatial self-organisation only occurs when specific nanoparticles are added to the liquid crystal (CL) mixture in certain quantities.

In fact, the liquid crystal molecules are attracted to the added nanoparticles due to their surface energy and line up around them in specific directions, thus making it unnecessary to induce further alignment by rubbing.

It has been verified that nanoparticles can influence the nematic order of liquid crystal molecules, thus leading to the possibility of further refining the optimised function of photomobile polymers.

With this in mind, the inventors were able to identify suitable concentration ranges of the nanoparticles used that would allow them to obtain photomobile polymers without rubbing, which exhibit improved performance including, inter alia, shorter photo-response times, increased sensitivity to radiation stimuli, as well as greater mechanical stability.

Further, it has been shown that thanks to this technical solution, the photomobile polymers obtained by the process of the present invention are responsive to infrared wavelengths and unpolarised sunlight.

Therefore, the process proposed in the present invention is faster, less laborious, and allows for more consistent and reproducible materials than those obtainable according to the teachings of the state of the art.

In other words, this technical solution allows for better performance of photomobile polymers, including higher Young's or flexural modulus and shorter radiation response times.

The inventors have thus also identified an innovative formulation of a photomobile polymer that can be produced economically while maintaining the mechanical and thermo-mobility characteristics of alternative state-of-the-art technical solutions. Further, the inventors have found an innovative process for 3D/4D printing of polymer resins to produce objects that are able to be deformed significantly and reversibly upon interaction with light. This process is an alternative to typical 3D resin printing techniques based on stereolithography (SLA) or digital light processing (DLP). In addition, the inventors have devised a handling device for a solar cell or photovoltaic panel comprising a photomobile polymer made according to the present invention with high thermomobility and cost-effective production characteristics.

### OBJECT OF THE INVENTION

At least one of the aforementioned technical problems is thus solved according to a first aspect of the present invention relating to a process for the preparation of a photomobile polymer comprising the following steps:
a) doping by incorporation into a non-cross-linked resin comprising at least one monomer and/or oligomer of liquid crystals having an azobenzene moiety of ZnO nanoparticles in a concentration greater than or different from 6% and less than or equal to 7.5% by weight, the value of 6% not being included, or silver nanoparticles in a concentration greater than 0.2% of the total, or silver nanorods in a concentration greater than 0.2% of the total, or carbon black in a concentration of 0.03% to 2%, provided that when doped with carbon black in a concentration comprised between 0.03% and 2% the at least one monomer and/or oligomer of liquid crystals may not have an azobenzene moiety
b) deposition of the doped polymer obtained at the end of step a) on a suitable substrate
   provided that at step b) the substrate is not subjected to rubbing.

It is thus a second and further aspect and object of the present invention to formulate a photomobile polymer obtained by the above-described process involving doping a non-cross-linked resin comprising at least one monomer and/or oligomer of liquid crystals having an azobenzene moiety with ZnO nanoparticles in a concentration greater than or different from 6% and less than or equal to 7.5% by weight, with the value of 6% not being included, or silver nanoparticles in a concentration greater than 0.2% of the total, or silver nanorods in a concentration greater than 0.2% of the total, or carbon black in a concentration comprised between 0.03% and 2%, provided that when the doping is with carbon black in a concentration comprised between 0.03% and 2% the at least one monomer and/or oligomer of liquid crystals may not have an azobenzene moiety, and its deposition on a suitable substrate in which the substrate is not previously rubbed.

According to a third and further aspect and object, the present invention claims a handling device for a photovoltaic panel, wherein said handling device comprises a frame.

Preferably, the frame is configured to accommodate at least one photovoltaic panel or similar technical devices, such as, for example, individual photovoltaic cells or small mirrors for solar thermodynamic applications.

Preferably, the handling device for a photovoltaic panel comprises a load-bearing element that is constrained with movement granted to said handling device so as to allow displacement from a first configuration to a second configuration.

Preferably, the handling device comprises at least one flexible element configured to move the frame between the first configuration and the second configuration.

Preferably, the flexible element is connected to or is a photomobile device comprising a photomobile polymer layer having at least partially the characteristics described above and configured so as to be exposed to incident light radiation and to produce by means of its photoreaction deformations displacement of said handling device between said first configuration and said second configuration.

With this solution, it is possible to provide a handling device for photovoltaic panels that is passively activated as a function of the incident radiation.

In this sense, this handling device does not require a power supply and is thus a very economical passive device.

Additionally, when the photomobile polymer adopted in said handling device produces movement as a result of interaction with sunlight, the handling device can behave as a solar tracker ideal for application in the solar and/or photovoltaic field.

It is therefore possible to design such a device so that solar radiation acts both as an energy source for the tracking movement of the photovoltaic panel and also for the implementation of the ideal type of tracking to be performed.

The present invention, in at least one of the aforementioned aspects, may have at least one of the further preferred features listed below.

Preferably, the photomobile polymer comprises a non-cross-linked resin comprising at least one monomer and/or oligomer of liquid crystals having an azobenzene moiety in a concentration comprised between 6 and 10 mol %, doped with ZnO nanoparticles in a concentration greater than or different from 6% and less than or equal to 7.5% by weight, the value of 6% not being included, or silver nanoparticles in a concentration greater than 0.2% of the total, or silver nanorods in a concentration greater than 0.2% of the total, or carbon black in a concentration of 0.03% to 2%, provided that when doped with carbon black in a concentration comprised between 0.03% and 2% the at least one monomer and/or oligomer of liquid crystals may not have an azobenzene moiety.

This ensures that the photomobile polymer obtained enjoys high reversibility in the specific thermomobility obtained.

Preferably, the photomobile device comprises a metal layer laminated onto the photomobile polymer layer on the opposite side to that on which said incident light radiation strikes.

This makes it possible to dissipate and even out the heat transferred by the incident radiation on the photomobile device.

Preferably, the handling device comprises a parabolic mirror constrained in close proximity to said photomobile device.

Preferably, the parabolic mirror is configured to collect the incident light radiation and concentrate it on the photomobile polymer layer.

This makes it possible to increase the incident light radiation on the photomobile polymer layer and thus further increase the performance of the handling device.

Preferably, the present invention concerns a method of 3D printing a photomobile polymer having at least the previously described characteristics, said method comprising arranging a tank configured to contain a predetermined amount of a non-cross-linked photomobile polymer resin.

Preferably, the tank comprises a handling device configured to move a movable bed inside the tank.

Preferably, the method comprises setting up an initial light source, comprised in the tank, configured to selectively irradiate a first predetermined cross-linking layer of the photomobile polymer at the movable bed, producing localised alignment thereof.

Preferably, the method comprises the provision of a second light source, comprised in the tank, configured to selectively irradiate a second predetermined cross-linking layer of the photomobile polymer at the movable bed producing cross-linking thereof.

Preferably, the method comprises placing non-cross-linked resin in the tank.

Preferably, the method comprises positioning the movable bed at the non-cross-linked resin to be polymerised.

Preferably, the method comprises heating the tank to a temperature that is hostile to non-cross-linked resin.

Preferably, the method comprises irradiating with the first light source the first cross-linking layer in such a way as to achieve a selective and localised alignment of said non-cross-linked resin, and/or irradiating with the second light source the second cross-linking layer in such a way as to sculpt the non-cross-linked resin by polymerising and aligning it.

Preferably, the method comprises completing the printing of the photomobile polymer by moving the movable bed by means of the handling device in order to irradiate with the first and/or second light source a new cross-linking layer distinct from the first or second cross-linking layer and repeating the steps described above as required.

Preferably, the present invention claims a 3D printer for printing a photomobile polymer having at least the previously described characteristics and preferably adopting the printing method having at least the previously described characteristics.

Preferably, the 3D printer comprises a tank configured to contain a predetermined amount of a non-cross-linked photomobile polymer resin. Preferably, the tank comprises a handling device configured to move a movable bed inside the tank.

Preferably, the 3D printer comprises a first light source configured to selectively irradiate a first predetermined cross-linking layer of the photomobile polymer at the movable bed, producing localised alignment thereof.

Preferably, the 3D printer comprises a second light source configured to selectively irradiate a second predetermined cross-linking layer of the photomobile polymer at the movable bed, producing cross-linking thereof.

Preferably, the first light source is a collimated lamp or strip of LEDs or a polarised source, preferably a polarised laser or an unpolarised laser associated with a polarising foil and a plurality of mirrors or photonic crystals configured to selectively and rapidly reflect said laser light at said first cross-linking layer.

In this way, an initial alignment of the non-cross-linked resin can be achieved selectively and effectively.

Preferably, the LED strip is configured to irradiate the said non-cross-linked resin in a pulsed manner.

This makes it possible to optimise the use of the LED strip by reducing electric power consumption and ensuring an ideal pattern in the resin to be cross-linked.

Preferably, the polarised source is polarised perpendicular to the movable bed and has a wavelength comprised between 330-457 nm, preferably between 350-365 nm. In this way, an optimal and precise polymerisation of a selectively defined layer of said non-cross-linked resin can be produced.

The Applicant has in fact found that polarised light is capable of producing the desired polarisation by isomerising azobenzene if and only if the polymerisation is not perpendicular to the azobenzene itself. If this condition is met, the azobenzene begins to isomerise until it spontaneously becomes perpendicular to the polarisation. This creates a necessary and prodromal condition for the self-alignment of the entire desired photopolymer.

At this point, the azobenzene molecules are all self-aligned and the ideal “guided” polymerisation of the remaining portions can begin.

Preferably, the first light source has a power density comprised between 0.8 and 2.8 W/cm².

Preferably, the first and/or second cross-linking layer has a thickness comprised between 10 microns and 50 microns.

In this way, it is possible to develop a sequence of effectively polymerised multi-layers that can guarantee the desired physical-mechanical properties even in a macroscopically large bulk structure.

Preferably, the movable bed is coated with an alignment layer to facilitate anchorage of liquid crystals comprised in the non-cross-linked resin.

In this way, it is possible to further increase the different designs of patterns according to which the molecules of the resin to be cross-linked can be aligned, increasing the adaptability and performance of the photomobile polymer that can be produced.

Preferably, the handling device comprises a parabolic mirror constrained in close proximity to the photomobile device.

Preferably, the parabolic mirror is configured to collect the incident light radiation and concentrate it on the photomobile polymer layer.

This increases light gathering and the efficiency of the photomobile device.

Preferably, the handling device comprising three photomobile devices configured in such a way as to move said handling device between said first configuration and said second configuration producing a complex rotation as the sum of several pure uniaxial rotations.

In this way, it is possible to produce variations in the configuration of the handling device that follow the movement of the light radiation on more than one axis of rotation, thus providing a more versatile and efficient type of tracking.

The characteristics and advantages of the invention will become clearer from the detailed description of a preferred embodiment thereof, shown by way of non-limiting example, with reference to the appended drawings wherein:

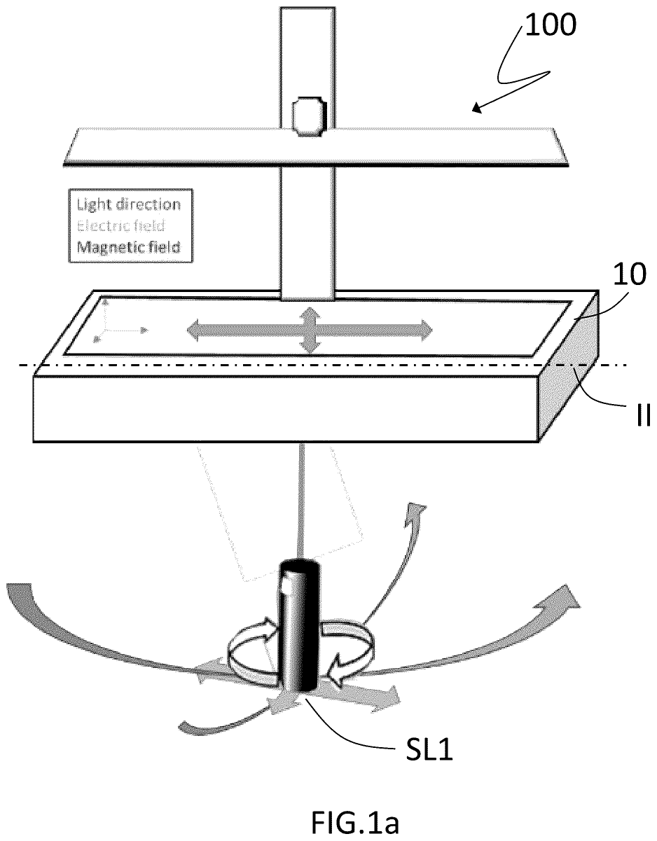

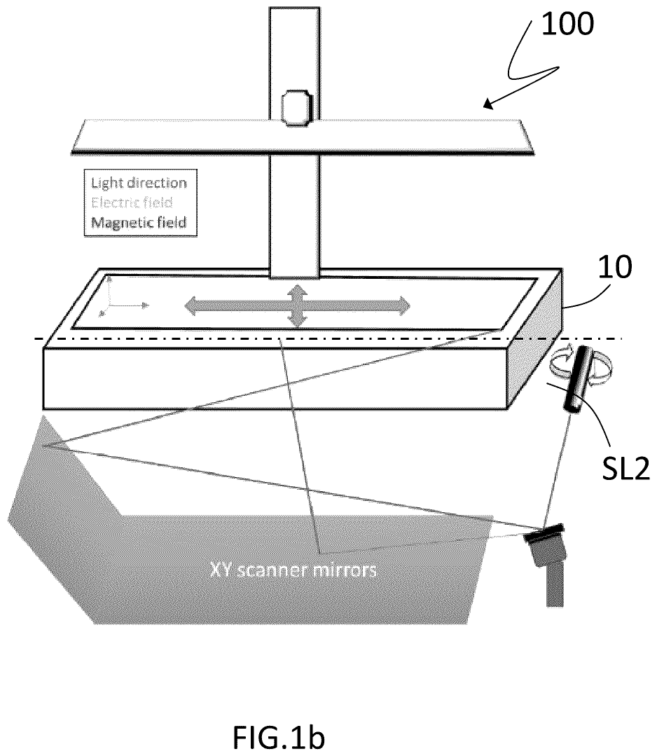

FIGS. 1a and 1b are respectively a front perspective view of two different embodiments of a printing method for a photomobile polymer according to the present invention;

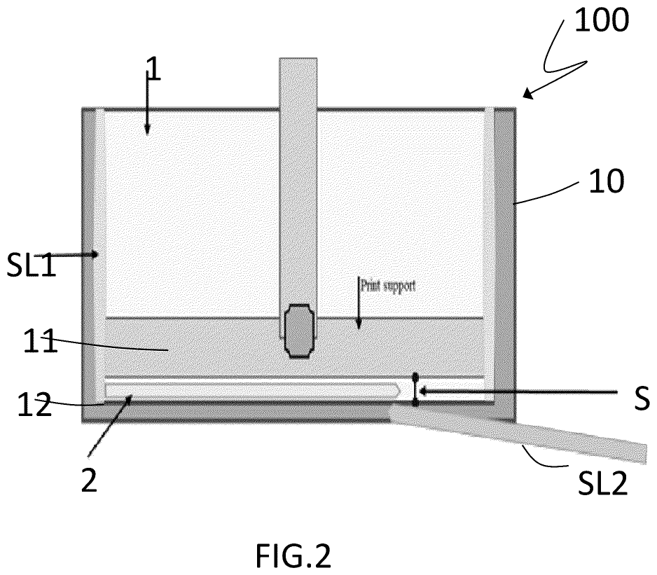

FIG. 2 is a schematic view of a section along plane II of the embodiment shown in FIG. 1a;

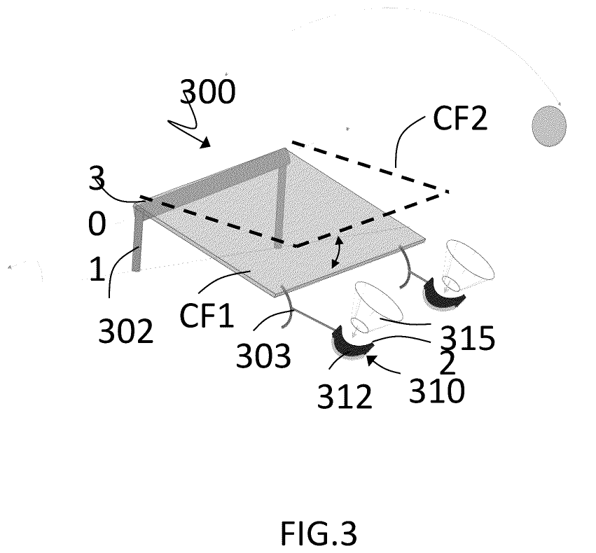

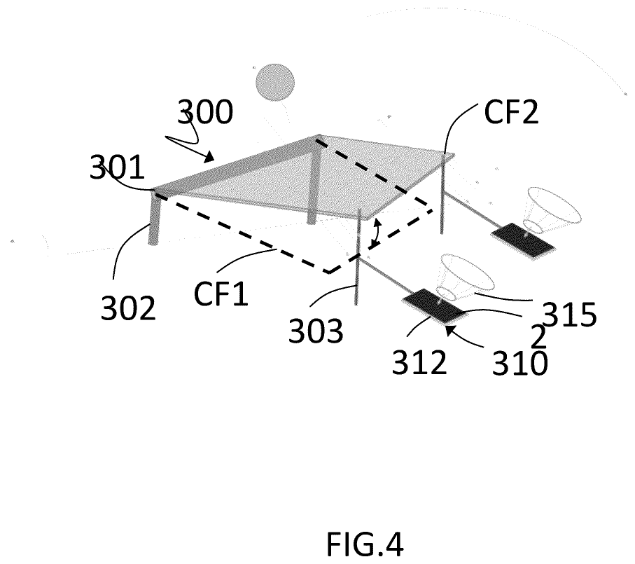

FIGS. 3 and 4 are two perspective views in different configurations of a handling device for a photovoltaic panel made in accordance with the present invention;

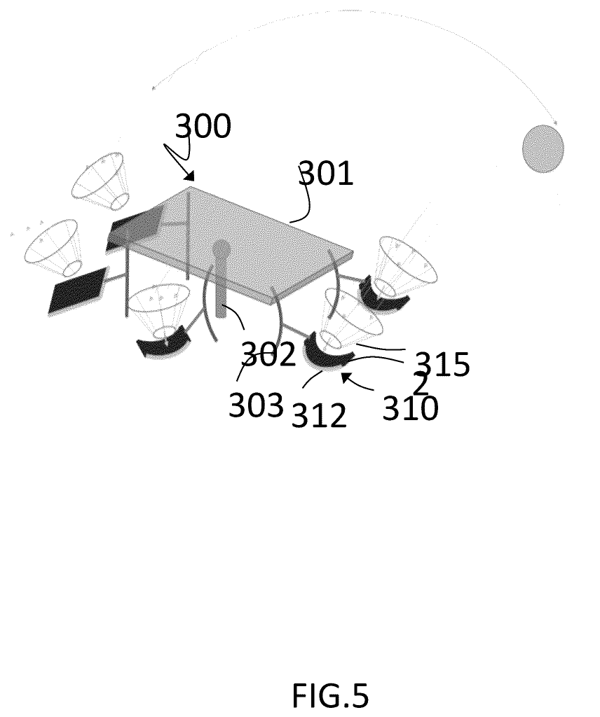

FIG. 5 is a perspective view of a further embodiment of a handling device for a photovoltaic panel made in accordance with the present invention;

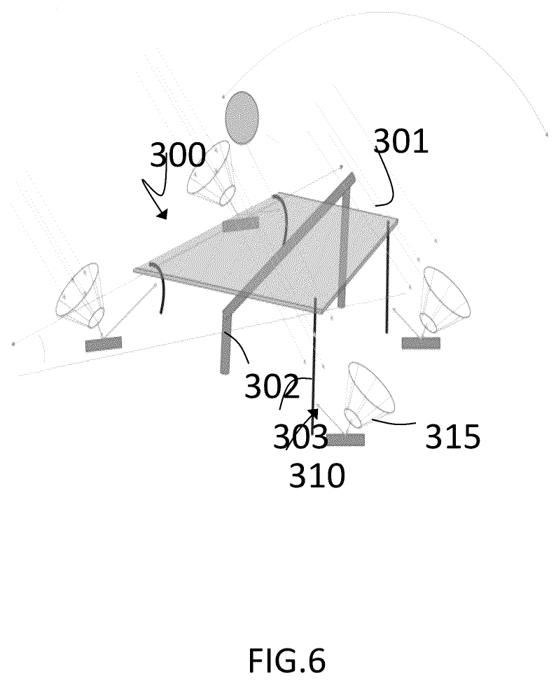

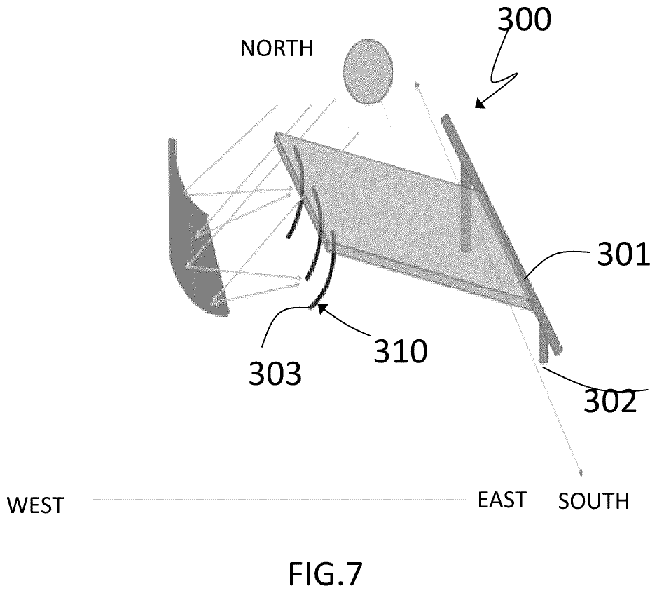

FIGS. 6 and 7 are respective perspective views of further embodiments of the handling device for a photovoltaic panel made in accordance with the present invention.

### DETAILED DESCRIPTION OF THE INVENTION

Within the meaning of the present invention, “doping” means the addition to the polymer of small percentages of foreign molecules that are not part of the polymer itself in order to modify its chemical-physical and functional characteristics.

Within the meaning of the present invention, “rubbing”, e.g. mechanical rubbing, refers to the process of ordering liquid crystal molecules in a specific direction and aligning them.

Again, the term “self-alignment” refers to an alignment process performed “spontaneously” by the resin according to the invention that the Applicant has discovered as a function of a specific chemical composition.

More specifically, the state of the art adopts resins comprising non-cross-linked liquid crystals that require a long-range alignment step in a physical direction in order to perform the desired selective actuation characteristics.

The Applicant has noted that the known technique adopts the use of the aforementioned “rubbing” to produce this desired alignment of misaligned liquid crystals.

The term “self-alignment” adopted here therefore identifies a material that has the ability to produce the desired long-range alignment without needing to be subjected to “rubbing”, but spontaneously produces, before or during the cross-linking step, internal reorganisation in such a way as to produce this long-range alignment.

It is further important to note that a “self-alignment” process spontaneously produced by a material has the advantage of being performed selectively and at the same time very reliable and reproducible, unlike other complex solutions in the state of the art.

Within the meaning of this invention, the term “pure uniaxial rotations” refers to rotations that produce a displacement of a solid body between two equivalent positions that are attainable through a rotation of the solid body about a single axis of rotation, with no further movement present.

The term “complex rotation” refers to a sum of pure uniaxial rotations acting simultaneously on different portions of a solid body such as to move said solid body between two equivalent positions in a way that cannot be achieved by a single pure uniaxial rotation.

The process for preparing a photomobile polymer 2 of the present invention comprises the following steps:
a) doping by incorporation into a liquid crystal polymer of ZnO nanoparticles in a concentration greater than or different from 6% and less than or equal to 7.5% by weight, the value of 6% not being included, or silver nanoparticles in a concentration greater than 0.2% of the total, or silver nanorods in a concentration greater than 0.2% of the total, or carbon black in a concentration of 0.03% to 2%, provided that when doped with carbon black in a concentration comprised between 0.03% and 2% the at least one monomer and/or oligomer of liquid crystals may not have an azobenzene moiety;
b) deposition of the doped polymer obtained at the end of step a) onto a suitable substrate provided that no rubbing process takes place in step b).

With regard to at least one of the previously described embodiments, after numerous targeted studies, the Applicant has found that when the concentration of ZnO nanoparticles is very specific and greater than or different from 6% and less than or equal to 7.5%, a surprising and advantageous synergistic process takes place between the liquid crystal portion and the ZnO nanoparticles, leading to a long range “self-alignment” of the liquid crystals.

In more detail, in fact, the Applicant found that inserting an amount of ZnO nanoparticles greater than 7.5% by weight begins to create aggregates between the nanoparticles themselves that are substantially depleted of the polymer matrix and become incapable of guaranteeing the homogeneity of the system and thus the uniformity of behaviour as photopolymers.

Furthermore, the Applicant has found that an inverse effect to that described above occurs when the concentration of ZnO is less than 6% by weight; in fact in this case, zones can be formed with no ZnO nanoparticles, thus creating islands of liquid crystals as such, which would need to be aligned (e.g. by rubbing) to preserve their photomobile properties.

A liquid crystal polymer may be any liquid crystal polymer characterised by the presence of liquid crystal monomers (LCM) and liquid crystal polymers (LCP) where “liquid crystal” means any mesophase-forming mesogenic compound, including lyotropic and thermotropic compounds. In general, it is appropriate to emphasise that monomer/polymer liquid crystals exhibit the properties of both monomers/polymers and liquid crystals.

According to an embodiment of the present invention, presented by way of non-limiting example, a liquid crystal photomobile polymer 2 is obtained by the polymerisation of a non-cross-linked resin 1 comprising at least one liquid crystal having one or more functional groups for the polymerisation, at least one azobenzene-based monomer, at least one monomer and/or at least one oligomer and/or at least one polymer or combinations thereof, in the presence of an initiator. Preferably, a glass or plastic substrate is used.

In other words, the photomobile polymer 2 according to the present invention is obtained by the process comprising doping a non-cross-linked resin 1 comprising at least one monomer and/or oligomer of liquid crystals having an azobenzene moiety with ZnO in a concentration greater than or different from 6% and less than or equal to 7.5% by weight, the value of 6% not being included, or silver nanoparticles in a concentration greater than 0.2% of the total, or silver nanorods in a concentration greater than 0.2% of the total, or carbon black in a concentration of 0.03% to 2%, provided that when doped with carbon black in a concentration comprised between 0.03% and 2% the at least one monomer and/or oligomer of liquid crystals may not have an azobenzene moiety.

The Applicant has noted that such ideal technical advantages are not achievable with any type of nematic liquid crystal, as it is necessary for applications as real and efficient final photopolymers to have a long-range nematic alignment in a directrix capable of responding with sufficient mechanical and physical characteristics. If this is not done, the resulting material will not be able to perform adequately and will therefore be deemed unsuitable.

The Applicant therefore identified the azobenzene moiety with ZnO nanoparticles in the specific claimed concentration as an ideal and synergistic combination of characteristics essential to achieve the desired photopolymeric behaviour and benefits.

Preferably, the process for the preparation of the photomobile polymer 2 comprises the deposition of said photomobile polymer 2 on a suitable substrate that has not previously undergone rubbing.

The photomobile polymer 2, according to the present invention, consists of a resin comprising at least one liquid crystal monomer and/or oligomer comprising an azobenzene moiety in a concentration comprised between 6 and 10 mol %, and ZnO nanoparticles in a concentration greater than or different from 6% and less than or equal to 7.5% by weight, the value of 6% not being included, or silver nanoparticles in a concentration greater than 0.2% of the total, or silver nanorods in a concentration greater than 0.2% of the total, or carbon black in a concentration of 0.03% to 2%, provided that when doped with carbon black in a concentration comprised between 0.03% and 2% the at least one monomer and/or oligomer of liquid crystals may not have an azobenzene moiety.

The portion (moiety) of azobenzene, which forms the photochromic portion of the photomobile polymer.

Preferably, the azobenzene is substituted with at least one functional group adapted for polymerisation linked to aliphatic chains consisting of 3 to 11 carbons.

More preferably, at least one functional group is chosen from the group consisting of acrylates, methacrylates, epoxies and/or combinations thereof.

Preferably, the liquid crystal monomer and/or oligomer alone or in combination has a nematic temperature comprised between 20° C. and 50° C. Preferably, the liquid crystal monomers/oligomers/polymers have a flexural or Young's modulus comprised between 0.3 and 1.3 GPa.

These flexural modulus or Young's modulus values are functional to the printing process in that they allow the printed material that will be obtained from the resin to move efficiently and with ideal reversible response times once irradiated by specific radiation, e.g. light.

Preferably, the initiator can be a thermotropic substance or a light-sensitive substance.

Preferably, the initiator is a photo-initiator sensitive to light comprised between 300 and 405 nm, or comprised between 405 and 680 nm.

By way of example, light-activated initiators can be chosen from the group consisting of: benzylcyclohexyl-benzoylperoxide (BAPO), acetylentriol benzoate (AB), α-Benzoyl-o-phenoxy-isopropylbenzene (BPO-F), tert-butylperoxy-2,4-dicarbonate (TBP-DC), A-phenoxy-2,4,6-trimethyl-1,3,5-triazine (TPT), Irgacure-651.

As a non-exhaustive example, temperature-activated initiators can be chosen from the group consisting of: azobisisobutyronitrile (AIBN), di-tert-butyl peroxide-dicarbonate (DTBP-DC), 2,2′-Azobis(2-methylethanol) (A ME), tert-butylperoxy-isobutyl peroxide (TBP-IBP), dicumyl peroxide (DCP).

According to an embodiment, the polymerisation process comprises the steps of:
a. mixing in the absence of organic solvents of the starting products, wherein the liquid crystals are present in a percentage comprised between 97% and 85% of the total mass of the azobenzene-based monomers/monomers/oligomers/polymer, the azobenzene-based monomer is present in a percentage between 6 and 10% of the total mass of the azobenzene-based monomers/monomers/oligomers/polymer, the monomers/oligomers/polymers not based on liquid crystals, are present in a percentage between 3 and 15% of the total mass of the azobenzene-based monomers/monomers/oligomers/polymer
b. Addition of the mixture obtained at the end of step a) of the initiator in a percentage comprised between 1% and 15% of the total of the mixture obtained at the end of step a) and polymerisation until the resin is obtained as the final product

Below, by way of non-limiting example, possible formulations are reported for the photomobile polymer 2 made according to the present invention.

The method 200 of 3D printing the photomobile polymer 2 with at least some of the previously described characteristics was then developed.

The invention is a new approach for 3D/4D printing (in which the time constant is added to 3D printing) of light-activated resins to produce objects that can move when interacting with a light stimulus. This effect can be achieved with the use of liquid crystals CL comprising photoswitchable moieties using an alternative approach to stereolithography SLA or resin 3D printing with digital light processing (DLP). As previously described, the invention concerns a new 3D printing process and/or 3D printer for quickly and efficiently obtaining three- and four-dimensional objects that can move when stimulated by light. The formulation of the resin as previously described is a significant factor, particularly for its use with different light sources, e.g. promoting alignment versus polymerisation and respecting alignment times versus polymerisation times.

Further, the addition of nanoparticles to the non-cross-linked resin of the photomobile polymer can facilitate the production process by avoiding alignments of certain regions/layers of the print.

In fact, by adopting the resin according to an aspect of the present invention, it is possible to implement the aforementioned “self-alignment”, which allows for a spontaneous long-range alignment phase without having to apply an interaction to the resin with a surface or medium that imposes a physical direction on the portion of liquid crystals.

It is immediately evident that the use of such a resin in the 3D (or 4D) printing process is significantly advantageous by combining the ease of implementation of such a printing process with the physical-mechanical properties of the resin for a desired photomobile polymer.

The 3D (or 4D) printer according to the present invention is configured to use the VAT polymerisation method, which preferably adopts UV light to polymerise liquid resins in a container (VAT).

As shown for example in FIG. 1a, the VAT container is a tank 10 made of polymer and/or metal material.

Again with reference to FIG. 1a, it can be seen that the tank 10 comprises a handling device 11 configured to move a movable bed 12 inside said tank 10. Such a handling device 11 is a track on which a pure translation slide or similar kinematic mechanism runs.

Again with reference to FIG. 1a, it can be seen that the movable bed 12 is a flat, horizontally oriented surface with a substantially square or rectangular cross-section. In the embodiments shown in FIGS. 1a, 1b and 2, the printer comprises a first and a second light source.

In the embodiment shown, the first light source is a light that stimulates the alignment (perpendicular to the electric field of the light) of the liquid crystals within the VAT while the second light source is configured to polymerise and/or self-align specific fractions of the object to be printed.

In particular, the second light source SL2 is a polarised or unpolarised laser capable of both triggering polymerisation for the construction of a three-dimensional object and of modifying the local self-alignment of the liquid crystals in certain parts of the printed material in a detailed and precise manner. This is intended to give the liquid crystals a defined general arrangement according to the first light source and alternative alignments for the different movement dimensions of the PMP (see also FIG. 2).

Again with reference to FIG. 1a, the first light source SL1 is configured to be movable at 180° with respect to a plane of the VAT tank 10.

Alternatively, and with reference now to FIG. 2, the first light source SL1 is a programmable LED strip housed in contact with the wall of the tank 10.

For the sake of clarity, although the aforementioned photomobile polymer printing process is preferably rapid and continuous, it is described below as being divided into different steps.

In particular, two methodologically distinct steps can be recognised within this process: alignment and sculpture.

The alignment step in the tank 10 of the non-cross-linked resin 1 of the photomobile polymer 2 can in turn be characterised by two different events.

The first event is the alignment itself, in which the liquid crystals CL comprised in the non-cross-linked resin 1 self-align, due to the presence and contribution of the azobenzenes, perpendicular to the electric field of the light radiated by the light source SL1 on the non-cross-linked resin 1 (see FIG. 1a).

The second event is an alignment whereby, if the initiator in the formulation is activated by the light source SL1, standard polymerisation may occur. This type of event is designed and defined according to the application and alignment required for the photomobile polymer 2.

The light source SL1 can be switched off if necessary or used in pulsed mode to achieve more complex structures and optimise the time of use. This methodological approach is also compatible with other printing methods, such as inkjet or gravure printing.

With reference to FIG. 2, it can be seen that the sculpture step is performed by activation of the second light source SL2.

In particular, this step allows for the detailed polymerisation and alignment of the liquid crystals CL of the non-cross-linked resin 1 of the photomobile polymer 2 in alternating patterns that facilitate the creation of a final polymeric article comprising the photomobile polymer 2 capable of moving, when exposed to specific radiative stresses, in multiple dimensions.

This second sculpture step features various second light sources SL2 depending on the application.

Two embodiments are described below, which are also non-limiting examples.

The first example is a simple configuration of the 3D printer 100 in which local or voxel alignment is not necessary.

In fact, in this case, the second light source SL2 is a simple lamp (not a laser) that polymerises the second cross-linking layer SR2, which essentially coincides with the first cross-linking layer SR1 that was mainly aligned by the first light source SL1. In this case, different shapes for different layers require the use of Transmissive LCD displays.

In this case, the photomobile polymer 2 has a single alignment direction and no modelled fraction.

When specific and complex patterning is required, the lamp of the second light source SL2 is replaced with another type of radiative source.

With reference to FIG. 1b, it can be seen that in the case of specific patterning, the second light source SL2 is either a polarised laser or an unpolarised laser with a polarising foil capable of moving on the XYZ axis or a set of mirrors or photonic crystals capable of moving the laser light to all points on the printable surface. In this case, the laser SL2 is configured to not only model the shape required for the photomobile polymer layer 2, but also to modulate different alignments in three dimensions, thus stimulating the formation of a complex mobility platform.

With reference to FIG. 2, it can be seen that in the case where said second light source SL2 is a polarised laser, it is possible to irradiate the non-cross-linked resin 1 at said movable bed 12 at an angle of incidence close to 0° so as to obtain an alignment parallel to the extension plane of the movable bed 12.

It is important to emphasise that the method 200 of 3D-printing a photomobile polymer 2 described here is advantageous over state-of-the-art techniques in at least two main respects.

The first is the use of collimated non-polarised light to align the azobenzenes comprised in the non-cross-linked resin 1, thus leading to an economic advantage over known solutions.

The second is determined by the possibility of using a second laser light source SL2 configured to locally polymerise the liquid crystals CL, producing a different local alignment from that produced in bulk at a more macroscopic level using the first light source SL1.

In order to emphasise the innovative effort made by the inventors, it is noted that by contrast in literature a complex and expensive technology including the adoption of a powerful magnet has been used, which could be a limited and non-exhaustive alternative to the proposed invention. Indeed, such a magnetic-based solution would not be suitable for creating alternating local alignments in the photomobile polymer 2. In fact, even if the magnet rotated rapidly around the tank, it would be very unlikely to have a precise three-dimensional alignment.

It seems appropriate to emphasise that an important portion of this invention is the non-cross-linked resin 1 which is used in the various aspects of the technology described above and claimed below.

In particular, liquid crystals CL are present in the non-cross-linked resin 2 used. Liquid crystal CL can be synthesised as an acrylate/epoxy/thiolenic monomer/polymer or other methodologies.

The resin could be composed entirely of liquid crystals CL or mixtures thereof variously blended with bulk monomers.

Further, the non-cross-linked resin 1 can be manufactured as an organic/inorganic blend, allowing for the addition of more intrinsic properties, so as to respond to multiple dimensions. An example that does not exclude other possibilities is the use of metal nanoparticles that adapt the incident light and thus the functionality of the photomobile polymer 2 PMP.

It is also interesting to consider that this 3D printer can polymerise said non-cross-linked resin 1 in the photomobile polymer 2 layer by layer, thus also offering the possibility of replacing or refilling the tank 10 containing an alternative resin with nanoparticles or other additives. In this way, different layers would give new dimensions to the print, opening up a wide range of applications.

Now, with reference to FIG. 3, a handling device 300 for photovoltaic panels is depicted.

The technical solution proposed and shown, for example, in FIG. 3 involves the use of photomobile polymers 2 included in a handling device 300 for a photovoltaic panel (or similar technology) in order to make the complete device more efficient, optimise orientation with respect to the direction of solar radiation and energy harvesting by cells or thermodynamic systems.

Preferably, the handling device 300 is arranged according to an east-west orientation of the sun.

With reference to FIG. 3, it can be seen that the handling device 300 comprises a frame 301 made according to an embodiment using tubular elements or metal or polymer profiles defining a structure with a substantially square or rectangular base. The frame 301 is configured in such a way that at least one photovoltaic panel can be selectively housed and constrained on it.

Alternatively, the frame 301 is configured to accommodate solar panels, mirrors or similar technical solutions.

Again with reference to FIG. 3, it can be seen that the handling device 300 comprises two load-bearing elements 302 constrained (or laid) at one end to a ground or installation surface and at a second end near two corresponding ends of said frame 301.

The two load-bearing elements shown in FIGS. 3 and 4 are also metal or polymer tubes or profiles.

The two load-bearing elements 302 are constrained to the frame 301 stably with granted rotation (e.g. by means of a hinge) so as to allow the frame 301 to move according to pure uniaxial rotation about an axis of rotation substantially coincident with the tubular extension of the frame 301 comprised between the two load-bearing elements 302.

Now with reference to FIGS. 3 and 4, it can be seen that this embodiment allows the handling device 300 to rotate between
a first configuration CF1, in which the frame 301 (and coherently the photovoltaic panel housed on it) is more inclined with respect to the ground and one of its ends, opposite the one constrained with granted rotation to the two load-bearing elements 302, is in a proximal position with respect to the ground itself, and
a second CF2 configuration, in which the frame 301 is substantially horizontal to the ground and said end opposite the one constrained with granted rotation to the two load-bearing elements 302 is in a distal position with respect to the ground itself.

The frame 301 is connected at said opposite end to the one constrained with granted rotation to the two load-bearing elements 302 to two flexible elements 304 configured to bend according to a certain mechanical stimulus and to guide the frame 301 in displacements between the first configuration CF1 and the second configuration CF2.

The two flexible elements 304 are chosen from materials, preferably polymer or metal, and shaped in such a way as to allow a large number of reversible displacements between the first and second configurations without inducing resistance or showing critical wear.

FIG. 3 shows the first configuration CF1, while FIG. 4 shows the second configuration CF2 of the frame 301.

As can be seen from FIGS. 3 and 4, the two flexible elements 304 are connected, i.e., preferably constrained together, respectively, to two photomobile devices 310 each comprising a photomobile polymer layer 2 made according to the present invention.

Each photomobile device 310 is preferably made as a multilayer and is essentially planar when at rest and not exposed to light radiation, while it assumes a folded configuration when exposed for a sufficiently long time to a specific light radiation.

The photomobile device 310 is configured to produce said mechanical stimulus for the flexible elements 304 so as to induce the displacement of the handling device 300 from the first configuration CF1 to the second configuration CF2.

As can be seen, for example, from FIG. 4, each photomobile device 310 is configured in such a way that it is exposed to solar incident light radiation and produces through its photoreaction deformations the aforementioned displacement of the handling device 300.

Again, each photomobile device 310 comprises the photomobile polymer layer 2 having a thickness, usually comprised between 40 μm and 60 μm, which can be adapted to the requirements of the application.

Preferably, the proposed handling device 300 also involves the combined use of photomobile polymers 2 and metal films 312 laminated onto them so as to dissipate and even out the temperature on the polymers themselves whose movement is activated by light radiation but not by thermal effects alone. In this case, the bending of the polymer films caused by light radiation will be used for the correct positioning of the photovoltaic panel.

With reference to FIGS. 3, 4 and 5, it can be seen that the handling device 300 comprises a parabolic mirror 315 constrained in proximity to said photomobile device 310 and configured to collect said incident light radiation and concentrate it on said photomobile polymer layer 2.

In other words, the handling device 300 is equipped with optical systems to collect radiation only along specific directions and to achieve the appropriate light intensity for the handling of the photomobile polymers 2 comprised in the photomobile device 310.

This further ensures effective transfer of movement to the photovoltaic panel or optical system to be handled.

The use of a metal layer 312 (in yellow in FIGS. 3, 4 and 5) makes it possible, if necessary, to dissipate some of the heat and even it out on the polymer film without irreversibly altering its behaviour, even at high concentrations.

Preferably, the metal layer 312 is made of copper or another conductive metal and has a thickness, usually less than 10 μm, which is in any case related to the mechanical properties required by the application.

The proposed handling device 300 is therefore automatically alignable and in particular the subsystem part involving mirrors or lenses (also called “compound parabolic collector” CPC) and photomobile polymers (PMP) can be associated with a kind of sensor such as Light Dependent Resistors (LDR) that can be used in tracking systems.

Further, it is crucial to add that the bending angle of the photomobile polymer is linearly dependent on the incident light intensity and this could simplify the identification of the angle at which the subsystem comprising the synergy between the compound parabolic collector (CPC) and the photomobile polymer (PMP) 2 should be placed.

FIG. 5 shows a further evolution of the proposed handling device 300 involving multiple degrees of freedom provided by a plurality of photomobile devices 310 and corresponding flexible elements 304 arranged in such a way that they do not bend in exactly the same way and define a dual-axis-like configuration.

As can be seen in FIG. 5, such a configuration preferably involves the use of a ball joint positioned substantially in the centre of the frame 301 as the load-bearing element 302.

According to an embodiment similar to that described in FIG. 5, the plurality of photomobile devices 310 is further constrained preferably by means of bars or similar technical solutions to an installation surface 320. This installation surface 320 is preferably made of metal or concrete in order to guarantee an effective and stable constraint with respect to the ground on which the handling device 300 is to be installed. Alternatively, the plurality of photomobile devices 310 is further constrained to said load-bearing element 302.

It is clear to a person skilled in the art that the construction and installation of the handling device 300 is done in such a way as to ensure a durable and reliable installation according to the different types of installation terrain chosen.

Now an embodiment is described in which a plurality of photomobile devices 310 is directly connected to the frame 301 in such a way that it is the deformation of the photomobile polymer layer 2 as a result of light excitation that induces the displacement of the frame 301 from the first configuration CF1 to the second configuration CF2.

In other words, in certain embodiments according to the present invention, the flexible element 304 is a photomobile device 310 directly connected to the frame 301. In the preferred embodiment, the frame 301 is constrained to the ground by a supporting element 302 similar in function to the one shown in FIG. 5, which in this case consists of an inverted U-shaped tubular element.

According to preferred embodiments, shown as an example in FIG. 6, the rays of incident light radiation are collected and concentrated by means of respective parabolic mirrors 315, reflected by means of any additional mirrors and sent to photomobile devices 310 in order to produce the desired solar tracking movement.

Similarly, the same operating principle is applied using a single parabolic mirror 315 that simultaneously irradiates a plurality of photomobile devices 310 directly constrained to the frame 301 as shown in FIG. 7.

### EXAMPLES

### Example 1: PMPs Doped with ZnO Nanoparticles

A preparation of different photomobile polymers (PMPs) doped with different percentages of zinc oxide (ZnO) nanoparticles is described: basic mixtures of liquid crystal polymers (53% mol MAPE, 6% mol A9zA9, 18% mol AOCB, 22% mol AOBM, 1% mol Phenylbis) were made, to which the following were added by weight, respectively:
1.5% ZnO,
3% ZnO,
6% ZnO,
7.5% ZnO
   thus obtaining four different mixtures of non-cross-linked resins.

Further, from these mixtures, photomobile polymers (PMP) were produced with and without rubbing, plus some undoped (for control and comparison) and doped with ZnO for a total of ten films.

Optical and thermal characterisation described in more detail below was carried out on these ten samples.

The ten different photomobile polymers (PMPs) prepared as described above were tested with two different lasers (at 405 and 457 nm wavelengths, respectively) and the maximum bending angle as a function of power density was derived.

The optical characterisation performed showed that as the percentage of ZnO increases, the film's ability to bend increases.

In particular, the presence of ZnO nanoparticles is necessary for good laser response in terms of bending.

Furthermore, in comparison with the control sample (undoped PMP), it can be seen that ZnO replaces rubbing, allowing the doped PMP film to bend much better than the control. It has been shown that photomobile PMP polymers doped with ZnO comprised between 6% and 7.5% by weight differ in that photomobile PMP polymers with a ZnO weight greater than 6% are able to reversibly return to the resting state when radiation is interrupted, whereas this behaviour does not appear to be highlighted by the further formulations.

Further thermal characterisations were carried out via differential scanning calorimetry (DSC) and thermogravimetry (TGA) to assess, respectively, the presence of an effect of the ZnO nanoparticles on the glass transition temperature (Tg) with respect to the undoped control photomobile polymer, and to confirm the weight percentages of ZnO actually present in the respective PMP photomobile polymers. Differential scanning calorimetry (DSC) analyses conducted show that the % of ZnO does not influence the glass transition temperature (Tg) of the photomobile polymer (PMP) as all the values are around 40° C.

Thermogravimetric analysis (TGA) shows that the percentage of ZnO does not influence the temperature at which 5% by weight is lost. There is a 6.55% residue in the control, due to carbon chains formed during the thermal process. For the other samples, the residue is the sum of these carbon chains plus the percentage of ZnO put into the photomobile polymer (PMP). For example, for the photomobile polymer (PMP) with 1.5% by weight of ZnO, the residue is 7.99%, which compared to the control residue (6.55%) is approximately 1.5% more, and likewise for the other photomobile polymers (PMP) tested.

Further comparison analyses were carried out on similar rubbed and unrubbed preparations, in particular, a control i.e. photopolymer undoped with ZnO and samples of photopolymers doped with increasing percentages of ZnO were prepared: 1.5%, 3%, 6%, 7%, 7.5%.

They were tested with two different lasers (with wavelengths at 405 nm and 457 nm) and the maximum bending angle was derived as a function of power density. The data showed that samples subjected to rubbing exhibit the mechanical directrix that liquid crystals follow according to the nematic temperature. This implies that samples without ZnO do not function beyond this value, but functionality is restored by the presence of ZnO, in a concentration comprised between 3 wt % and 7.5 wt %, wherein above 6 wt %, performance improves as a function of the wavelength of 457 nm.

Thus it has been noted that when not rubbed, the samples do not exhibit the mechanical directrix that liquid crystals follow at the nematic temperature, however, the performance is better than the relative samples cross-linked on substrates treated with rubbing particularly at ZnO concentrations greater than 6 wt %.

### Example 2: PMP Doped with Silver Nanoparticles or Nanorods

LC monomers 4-methoxybenzoic acid 4-(6-acryloyloxyloxy)phenyl ester (MAPE), 4-[4-[6-Acryloxyhex-1-yl)oxyphenyl]carboxybenzonitrile (AOCB), 1,4-Bis-[4-(6-acryloyloxyhexyloxy)benzoyloxy]-2-methylbenzene (AOBM), 4,4′-Bis[9-(acryloyloxy) nonyloxy]azobenzene (A9ZA9) were purchased from Synthon Chemicals (Germany) and the photoinitiator Bis(2,4,6-trimethylbenzoyl)-phenylphosphineoxide from Sigma Aldrich. Elvamide was supplied by Beamco. Other chemicals were supplied by Sigma-Aldrich.

The photo-actuator synthesis cells were prepared using plastic slides and spacers. Each slide was cut to the required size using a diamond drill bit. They were then washed in sequence first using a liquid glass cleaner, then ultrapure water, acetone (20 minutes) and finally ethanol. For each step, the slides were kept in an ultrasonic bath for 10 minutes. Once dry, they were spin-coated (3 sec 4000 rpm, 30 sec 4000 rpm, 3 sec 0 rpm) using Elvamide (6% w/w in methanol). Finally, the slides were scrubbed automatically using a home-made automated machine. The rubbed sides of two slides were faced antiparallel to the rubbed direction and spaced with a 50 μm thick layer of Kapton to obtain a cellular reactor.

PMP films were prepared using a mixture of LC monomers proposed by Rahikainen, M.; Zeng, H.; communications, AP-N.; 2018, undefined Reconfigurable photoactuator through the synergistic use of photochemical and photothermal effects. nature.com. 53 mol % of LC monomer MAPE, 18 mol % of LC monomer AOCB, 22 mol % of diacrylate cross-linker AOBM, 6 mol % of azoic cross-linker A9ZA9 and 1 mol % of photoinitiator Bis(2,4,6-trimethylbenzoyl)-phenylphosphineoxide. In short, the reaction mixture was dissolved in dichloromethane and heated to 70° C. until all the solvent was removed. The reaction mixture was then left to recrystallise in a refrigerator at room temperature overnight until it became a compact powder.

The reaction cell was heated to 100° C. and the mixture was infiltrated by capillary action. After infiltration, the sample was moved to a second hot plate placed at the nematic temperature (50° C.) and photopolymerised for 1 h (30 minutes per side) using a UV lamp emitting at 405 nm (12 mW/cm²) and then left for 24 hours at 50° C.

The doping process was performed following a protocol described in Sagnelli, D.; Calabrese, M.; Kaczmarczyk, O.; Rippa, M.; Vestri, A.; Marchesano, V.; Kortsen, K.; Crucitti, VC; Villani, F.; Loffredo, F.; et al. Improved photoreactivity of photomobile polymer actuators based on a novel Lcs/azobenzene copolymer and a network of Zno nanoparticles. Nanomaterials 2021, 11, doi: 10.3390/nano11123320, with some amendments. In brief, batches of freeze-dried SNC were mixed with the pre-dried LC mixture in a centrifuge tube to obtain a noble metal concentration (w/w) of 1%, 0.5% and 0.25% (w/w). Subsequently, the mixture was infiltrated into the cell reactor and polymerised under UV light as described above. The samples were labelled with the concentration of azobenzene and SNCs in the mixture, e.g. 6% Azo-PMP-1% SNC. Silver/gold nanocubes were prepared by growing gold nanorods with a silver shell. Cetrimonium-coated gold nanorods were initially synthesised according to a variant of the protocol developed by Vigdermann, L.; Zubarev, ER High-yield synthesis of gold nanorods with a longitudinal SPR peak greater than 1200 Nm using hydroquinone as reducing agent. Chim. Madre. 2013, 25, 1450-1457, doi: 10.1021/cm303661d and described in Centi, S.; Cavigli, L.; Borri, C.; Milanesi, A.; Banchelli, M.; Chioccioli, S.; Khlebtsov, BN; Khlebtsov, NG; Matteini, P.; Bogani, P.; et al. Small thiols stabilise the shape of gold nanorods. J. Fis. Chim. C 2020, 124, 11132-11140, doi: 10.1021/acs.jpcc.0c00737, in order to obtain longitudinal modes of plasmonic oscillations peaking between about 1000 and 1100 nm. Subsequently, the synthesised gold nanorods were coated with a silver shell according to the protocol reported in Milanesi, A.; Magni, G.; Centi, S.; Schifino, G.; Aluigi, A.; Khlebtsov, BN; Cavigli, L.; Barucci, A.; Khlebtsov, NG; Ratto, F.; et al. Optically activated and interrogated plasmonic hydrogels for applications in wound healing. J. Biofotonica 2020, 13, e202000135, doi: 10.1002/JBIO.202000135e. Khlebtsov, B.; Khanadeev, V.; Khlebtsov, N. Surface-enhanced Raman scattering within Au@Ag Core/Shell Nanorods. Ris. Nano 2016, 9, 2303-2318, doi: 10.1007/s12274-016-1117-7. Briefly, the particles were transferred at a nominal concentration of 200 μM Au in a solution containing 20 mM cetrimonium chloride (CTAC) and supplemented with 400 μM AgNO3 and 1.6 mM ascorbic acid. This molar ratio of Ag:Au around 2:1 was intended to convey a blue shift of the longitudinal modes of gold nanorods above 200 nm [doi: 10.1002/jbio.202000135]. After 2 h at 70° C., the particles were brought to a concentration of 1.6 mM Au in a 100 mM acetate buffer pH 5.0 containing 500 UM CTAC, 0.005% (w/w) polysorbate 20 and 50 μM mPEG-SH, in order to achieve amphiphilic termination and delay the onset of oxidative degradation of the silver shell. After 2 hours under gentle agitation at 37° C., the suspensions were purified and transferred to ultrapure water containing 0.005% (w/w) polysorbate 20 before further handling. Similarly, silver/gold nanocubes were prepared by overgrowing gold nanospheres with a silver shell. Gold nanospheres were synthesised from the same seeds used for the preparation of gold nanorods, which were diluted 1:80 in 73 mM CTAC, 27 mM ascorbic acid and 180 μM HAuCl4. The protocol for the addition of silver and mPEG-SH was the same as above. However, in this case, the Ag:Au ratio was about 10:1. After PEGylation, the particles were stored under the same conditions and with the same total noble metal concentration as the silver/gold nanocubes. For integration into an aromatic polymer, all the particles were formulated as dry power by implementing a freeze-dryer from Labconco (MO, USA) and stored under reduced vacuum in an attempt to further hinder oxidative loss of the silver shell.

Spectral characterisation in the UV/VIS range of PMP films (thickness ≈50 μm) was performed using a JASCO V-650 UV/VIS spectrophotometer (accuracy 0.5 nm, range 190-850 nm, Oklahoma, OK, USA). Both the total percentage transmittance T (%) and the total percentage reflectance R (%) were measured using a JASCO ISN-722 integrating sphere (inner diameter 60 mm, range 200-870 nm).

The PMPs were further characterised to see whether metal nanoparticles would reduce the decay time of the cis-isomer of azobenzene. The PMPs were irradiated for 10 minutes using a 405 nm polarised laser at a power density of 1.5 mW/cm<sup>2 </sup>. Subsequently, their optical absorbance was measured after 75 minutes in the dark. The optical absorbance was calculated as A (%)=100−T (%)−R (%).

Thermographic measurements of the PMP films during and after laser irradiation were carried out using an AVIO TVS 500 LWIR camera (spectral range 8-14 μm, FPA, 320×240, VOx microbolometer, temperature resolution ~0.05 K) mounting a standard 22 mm lens. For time-resolved trends, images were recorded at a frame rate of 20 Hz. The emissivity of the film was set at 0.93. All the measurements were taken at a laboratory temperature of 23° C. and humidity of 50%.

The PMP samples were characterised morphologically by atomic force microscopy (AFM, NT-MDT). The analysis was performed in a semi-non-contact configuration using high-resolution gold silicon cantilevers.

An Olympus BX60 optical microscope with crossed polarisers and 20× magnification was used to characterise the polymer films. Images of bare and metal-doped PMPs were taken at room temperature and the samples were set both parallel and at 45 degrees to one of the polarisers. These measurements demonstrated nematic order in both bare and metal-doped films, based on the resulting optical activity.

To study the dynamic response of PMPs, both bare and metal-doped actuators were cut as cantilevers (5 mm×1 mm) and irradiated at 405, 457, 532 and 785 nm with 100:1 polarised lasers. The set-up consisted of a neutral density filter, a retarding wave plate (λ/2), a focusing lens and a sample holder mounted on a 3D translator. The movements of the cantilevers were recorded at 60 fps. The videos were decompressed using virtualDub (v1.10.4). The deflection angle was measured relative to the initial position of the cantilever. The angle was converted to radians and arc length (mm) and the velocity was calculated in m/s. The time to reach maximum deflection was derived by counting the number of frames required for the cantilever to complete its deformation. In addition, the PMPs were tested with non-polarised white light (halogen lamp) and natural daylight.

For easy integration into PMP systems, the SNCs were freeze-dried and mixed as a powder with the LC mixtures. The composite mixtures were cast, injected into a home-made cell and polymerised.

The first characterisation concerned their birefringence, to understand whether the LCs retained their nematic organisation after doping. Interestingly, the PMPs containing both azobenzene and SNC displayed an increase in optical transmittance when the films were rotated by 45° relative to the polarisers. When the azobenzene was removed from the mixtures, this effect became even more noticeable. This result indicates that the synthesis process of the nanocomposites is consistent and reproducible and that the SNCs (2, 1, 0.5, 0.25% w/w) do not interrupt the nematic order of their host.

Next, the PMP films were characterised for their topography in order to understand whether the SNCs influence their surface roughness. The AFM measurements showed that the SNCs do not segregate on the surface but are well dispersed within the polymer matrix, probably due to the intermolecular interactions between the LC chains and PEG used as a particle coating. The PMPs without SNCs did not show holes but only the typical features of the rubbing process.

The use of noble metal nanocuboids as a means to improve the wavelength sensitivity of azobenzene-based PMPs for solar energy harvesting was tested.

Thermal response measurements were initially acquired using laser light at two different wavelengths (457 and 785 nm) and a thermal imaging camera. At a wavelength of 785 nm, it does not interact with the undoped pristine PMP but overlaps with the plasmonic resonance of the SNCs.

The exposed surface of the PMP containing the SNCs heats up in proportion to the incoming power density due to a photothermal plasmonic effect. In contrast, for the PMP without SNC, the thermal imaging camera did not detect any heat because the LC matrix absorbs very little light in the near-infrared window. When using a laser emitting at a wavelength of 457 nm, both the PMPs showed a consistent increase in heat attributed to the optical absorbance of azobenzene.

At high power density, the SNC-doped PMP showed temperature saturation, which could indicate a higher dissipation effect.

The optical absorbance of the 6% Azo-PMP-SNC and 0% Azo-PMP-SNC films was measured both before and after irradiation with 785 nm light. The PMP without azobenzene showed no change, however, when azobenzene was present, the optical absorbance underwent an abrupt transition indicating a chemical change in the polymer matrix.

The evolution of the optical absorbance of azobenzene and its trans-cis-trans isomerisation was measured. In particular, 6% Azo-PMP and 6% Azo-PMP-SNC were prepared fresh and their absorbance was measured. Subsequently, both films were irradiated with a UV lamp centred at 405 nm for 10 minutes and their absorbance was measured again. Afterwards, the PMPs were kept for 75 minutes in the dark and eventually showed a different optical absorbance pattern. In fact, when SNCs were present, the azobenzene component showed a much faster change in optical absorbance, and thus transitioned from its cis to trans isomers. In contrast, in the absence of SNC, no significant change was detected after 75 minutes in the dark.

Experimental evidence points to a dual interaction mechanism between the azobenzene portions and SNCs.

The optical absorbance of bare and metal-doped PMPs clearly shows that the SNCs increase the quantum yield of the system when irradiated with NIR light.

When only SNCs (0% Azo-PMP-1% SNC-Supplementary) or only azobenzene (6% Azo-PMP-0% SNC) are present, the system shows no increase in absorbance after irradiation.

This behaviour is interpreted as NIR-induced isomerisation of azobenzene catalysed by the SNCs, which increase the quantum yield of the system from 0. This catalytic effect is the first interaction between azobenzene and the SNCs. In particular, SNCs can release photoelectrons that can be captured by the azobenzene fractions that populate their LUMO level. The distance between the Fermi level of the SNCs and the LUMO line of azobenzene must be less than about 2 eV, which is the gap between the HOMO and LUMO lines of azobenzene, and can be easily reached by the photoelectrons released by the nanoparticles under resonant excitation. The ejection of photoelectrons is an ultra-fast process that can result in a build-up of charge that can be removed and transferred through the azobenzene moieties.

The so-called dark isomerisation effect has also been observed, which occurs whether the wavelength used for excitation was absorbed by azobenzene or the SNCs. In particular, in the case of an NIR laser (785 nm), the release of photoelectrons ceases when irradiation ceases and the charge flow reverses so that the SNCs facilitate cis-trans reisomerisation.

The system was tested in a macroscopic environment, so that the PMPs were cut overhanging (5 mm*1 mm) to see if the photoelectric effect could improve the bending capacity at various wavelengths. A laser emitting at a wavelength of 457 nm was tested, as the LC mixtures used undergo efficient activation under such conditions.

The samples considered for this experiment were a control named 6% Azo-PMP-0% SNC without any metal doping, and 6% Azo-PMP containing 0.25, 0.5, 1 and 2% (w/w) SNC. All samples bent efficiently even at low power densities. For example, the control bent up to 15 degrees with an optical power density of 2 W/cm². The samples doped with metal even at the lowest concentrations of SNC performed better than the control and showed a clear effect of SNC concentration. The higher the concentration of SNCs, the higher the tension. Even when the laser wavelength was not in full resonance with the plasmonic band of the SNCs, their presence was found to improve the performance of the nanocomposite material. This may concern the residual absorbance of SNCs between 400 and 500 nm or a broadening of their plasmonic oscillation spectrum as a result of the onset of particle aggregation.

The best performance was obtained from 6% Azo-PMP-1% and 2%, as both samples displayed a deflection that was about 6 times higher than the control at 3 W/cm². Interestingly, a saturation effect was observed after the 1% SNC concentration, as there was no further enhancement until 2% when the PMP was irradiated with light at 457 nm. The same experiment was repeated with a laser polarised at 785 nm, in order to assess the response of bare, metal-doped PMPs to NIR light. A concentration effect was evident when increasing the metal content and a threshold at 1% was identified for efficient conversion of NIR light into elastic energy. PMP performance improved by a factor of up to 4 from 1 to 2%. Moreover, the sample containing 2% SNC went into self-vibration, thus another indication that there is more than just a thermo-elastic component in the underlying mechanism. In the past, this effect only occurred when azobenzene was stimulated with UV light, and is only possible in the presence of a reversible trans-cis-trans isomerisation process.

Subsequently, the 1% and 2% SNC samples were chosen for further characterisation with other wavelengths. In particular, lasers at 405, 457, 532 and 785 nm were compared to explore interactions between azobenzene and SNC. The results confirmed that the SNCs were able to improve the conversion of light into mechanical work for all wavelengths. In particular, metal-doped samples performed better than the controls even when the light was optimally or suboptimally absorbed by azobenzene (405 and 457 nm). Under these conditions, the 6% Azo-PMP-2% SNC bent 1.5 to 4 times more than the controls. The NIR light was able to trigger the movement of the metal-doped sample as efficiently as at 405 and 457 nm, while the control remained motionless at 785 nm. This result shows a clear parallelism between the mechanical and optical characterisation of metal-doped samples. Indeed, the mechanical behaviour supports the hypothesis that the movement induced by NIR light is not only due to a thermoelastic effect but also to some interaction between azobenzene and SNCs. SNCs have both been shown to mediate an increase in the temperature of their host and a change in the optical absorbance of azobenzene when hit by NIR light. Metal-doped PMPs are not only capable of bending but also of self-vibrating. These dynamics suggest that, when the 785 nm laser is switched on, the SNCs release photoelectrons that excite the azobenzene portions to isomerise and, when switched off or dimmed, they recover the emitted charge, thus stimulating bending and vibration.

We correlated all these data to the solar irradiance of individual wavelengths measured outside the atmosphere to one astronomical unit from the sun in September 2001. All the values were then reduced by a constant factor of 50% from 405 to 532 nm and 5% for 785 nm in order to simulate the effect of atmospheric absorbance. Using these standardised data calibrated with our experimental measurements, it was quantitatively hypothesised how metal-doped PMPs would bend more than bare PMPs under exposure to sunlight. It was estimated that, with 1% SNC, the PMP would bend about 2.4 times more than the control. Adding 2% SNC to the mixture would cause bending up to 3.4 times better than the control. These multipliers were calculated only by considering the solar energy density at the individual wavelengths tested in the laboratory.

The PMPs and SNCs were also tested under incoherent, non-polarised light (halogen lamp and natural daylight) to see whether nanocomposite films could function and thus be suitable for solar energy harvesting under real environmental conditions. Three samples were tested with the halogen lamp, namely 6% Azo-PMP-2% SNC, 0% Azo-PMP-2% SNC and 6% Azo-PMP-0% SNC. All the samples were stimulated at a high power density of 4100 W/m 2 displaying a wide wavelength range between 400 and 1100 nm. This experiment first shows that no thermoelastic effect is involved in the movement of metal-doped PMPs, and that the use of non-polarised light is only effective for PMPs containing SNCLo 0% Azo-PMP-2% SNC bends only 13 degrees, while 6% Azo-PMP-2% SNC responds approximately 10 times more than the control. This confirms that the thermoelastic effect is only a small part of the factors synergised in metal-doped PMPs. In addition, the increased bending of PMPs in the presence of azobenzene shows that SNCs are essential to allow isomerisation even when non-polarised white light is used. When 6% Azo-PMP-0% SNC was tested under unpolarised white light, its curvature was only 9 degrees, thus reconfirming that the control sample needs both polarised and UV-rich light.

The PMPs were also tested using natural, filtered focused sunlight outdoors. Metal-doped PMPs are able to bend where the control does not do so appreciably. In fact, the metal-doped PMP is able to bend and vibrate when irradiated in full sunlight or even behind a 615 nm high-pass filter for compatibility with various uses of visible light. Instead, the control bends just 1 degree and remains stationary when the visible light is interrupted as shown in table 1. In addition, the metal-doped PMP readily enters self-vibration while being irradiated with ambient sunlight.

These results are unprecedented and remarkable for solar energy harvesting for two reasons: i) the first is the use of ambient sunlight using low-content azobenzene materials; ii) the second is that metal-doped PMPs respond efficiently to non-polarised, artificial or natural light, thus improving the efficiency and reducing the cost of any device that might use such materials for conversion.

TABLE 1

| Name | Maximum bending (°) |
|---|---|
| 6% Azo-PMP-2% SNC (sunlight) | 151 |
| 6% Azo-PMP-2% SNC (sunlight + | 86 |
| red filter) | |
| 6% Azo-PMP-0% SNC (sunlight) | 1 |

### Example 3: Doping with Carbon Black (Carbon Black CB)

The PMP and PMP/CB films were prepared using a mixture of LC monomers: 53 mol % of LC monomer MAPE, 18 mol % of LC monomer AOCB, 22 mol % of AOBM, 6 mol % of azo cross-linker A9ZA9, and 1 mol % of photoinitiator. The reaction mixture was dissolved in dichloromethane and heated at 50° C. for 1 hour. Then, the reaction mixture was allowed to recrystallise at room temperature until the solvent was completely removed. For the PMP/CB films, different amounts of CB (from 0.03% w/w up to 2% w/w) were added to the monomer mixture and mixed in a mortar until a uniform mixture was obtained. After the films were made, some preliminary tests were carried out, not reported here for the sake of brevity, which gave us an indication that the 0.1% percentage was the one that guaranteed the best performance in terms of bending and mechanical immobility, and so from now on we will only focus on this percentage. The CB solid was previously obtained by drying the corresponding volume of CB suspension (3 mg/ml in 1,1,1,3,3,3-hexafluoro-2-propanol) at room temperature. The reaction cell was heated to 100° C. and the monomer or CB/monomer mixture was infiltrated into the reactor cell by capillary action. After infiltration, the sample was moved to a second hot plate set to the nematic temperature (52° C.) and photopolymerised for 1 h (30 min per side) using a UV lamp with light λ=400 nm (12 mW/cm²) and then left for 12 h at 50° C.

For experiments to observe the behaviour of PMP at wavelengths not suitable for azobenzene isomerisation, a laser centred at 532 nm was also used. The laser diodes used were: MDL-III 405 nm 200 mW, MBL-F 457 nm 200 mW, MGL-F 532 nm 2 W.

Thermal measurements were taken using a FLIR ONE PRO Android (MICRO USB) thermal imaging camera, in the range of −20° C. to +150° C., with a thermal resolution of 160×120 pixels, a frame rate of 8.7 Hz and a sensitivity of 150 mK. The emissivity was set via software on the opaque surface to a value of 0.95 and the apparent reflected temperature to 300 K. The maximum temperatures were evaluated in real time by image analysis and optical images simultaneously recorded to detect anomalies in the deformations of the sample.

In this study, the behaviour of the PMP film was therefore evaluated, and how the presence of CB affects PMP in terms of broadening the bending efficiency, and all the samples (PMP (AZO) and PMP (AZO)/CB) were irradiated at a wavelength of 532 nm, close to the limit of the azobenzene absorption bandwidth, to test the response of PMP at a wavelength where isomerisation is less likely.

As expected, it is difficult for standard PMP film to respond to this wavelength. In fact, at 20 mW, no movement is detected and only at 70 mW can very appreciable movement be detected. To determine the bending angle, tangents were plotted before and after laser radiation near the point of impact.

Instead of pure PMP (AZO) films, PMP films doped with CB (PMP (AZO)/CB) show a good response when exposed to 532 nm laser irradiation. In fact, even at 20 mW macroscopic motion is detected and the observed bending is similar to pure PMP (AZO) samples in the bandwidth of the azobenzene isomerisation wavelength.

Analysing the bending angle trend as a function of laser power, it was seen that there are substantial differences between uncontaminated PMP (AZO) film and those doped with CB (PMP (AZO)/CB). Indeed, the PMP (AZO) samples respond well, as expected, in the UV-BLUE region but have great difficulty bending at 532 nm. On the other hand, PMP (AZO)/CB shows a completely complementary trend and although they have a lower bending efficiency in the UV, they have a good response at 457 nm and a very good response at 532 nm.

To explain the mechanism responsible for the bending of PMP even at wavelengths far from the typical bandwidth of azobenzene isomerisation, it is essential to study the contribution of temperature to azobenzene isomerisation. In general, isomerisation in the azobenzene molecule is activated by light radiation but is also closely linked to heat. In fact, before excitation, the most stable state is the trans isomer (left). Generally, trans→cis switching can be achieved by irradiation with light having wavelengths in the UV region, while the cis→trans back reaction can occur using visible light or heat. This is why temperature is a parameter to be considered in this type of measurement.

The temperature variation measured for uncontaminated PMP (AZO) and PMP (AZO)/CB composites was measured during laser irradiation performed at different wavelengths and powers. It can be observed that for all samples with good efficiency (high bending at lower power), the temperature reached is always comparable and, moreover, the trend of Δ T as a function of light power is always very similar. Conversely, for samples where the temperature is lower, there is also a substantial drop in efficiency. This is particularly marked for PMP (AZO) samples at 532 nm and PMP (AZO)/CB samples at 405 nm where there was some difficulty in moving. It is likely that temperature facilitates both directions of the reactions because the background energy increases and probably in this case only partial isomerisation on the azobenzene molecules is achieved because an attempt is made to bend the sample at a much longer temperature than that used for azobenzene isomerisation (UV region).

In conclusion, the possibility of broadening the usable spectral bandwidth of the samples was noted. In particular, by using a green laser (532 nm), where the PMP (AZO) response is low, a substantial improvement in bending efficiency is achieved at a fixed light power. In addition, a close relationship between measured temperature and bending efficiency due to wavelength radiation was shown.

Using a similar procedure, a carbon black-doped photopolymer was prepared in which the monomers do not contain azobenzene and in which the CB concentration is 0.1 wt %.

1. A process for preparing a photomobile polymer (2) comprising the following steps:
(a) doping by incorporation into a liquid crystal polymer:
(i) ZnO nanoparticles in a concentration greater than 6% by weight and less than or equal to 7.5% by weight, the value of 6% not being included,
(ii) silver nanoparticles in a concentration greater than 0.2% of the total,
(iii) silver nanorods in a concentration greater than 0.2% of the total, or
(iv) carbon black in a concentration of 0.03% to 2%, provided that when doped with carbon black in a concentration comprised between 0.03% and 2% the at least one monomer and/or oligomer of liquid crystals may not have an azobenzene moiety; and
(b) depositing the doped polymer obtained at the end of step a) onto a suitable substrate provided that no rubbing process takes place in step b).

2. A photomobile polymer (2) obtained by a process comprising:
doping a non-cross-linked resin (1) comprising at least one monomer and/or oligomer of liquid crystals having an azobenzene moiety with:
(a) ZnO nanoparticles in a concentration greater than or different from 6% and less than or equal to 7.5% by weight, with the value of 6% not being included,
(b) silver nanoparticles in a concentration greater than 0.2% of the total,
(c) silver nanorods in a concentration greater than 0.2% of the total, or
(d) carbon black in a concentration comprised between 0.03% and 2%, provided that when the doping is with carbon black in a concentration comprised between 0.03% and 2% the at least one monomer and/or oligomer of liquid crystals may not have an azobenzene moiety, and its deposition on a suitable substrate in which the substrate is not previously rubbed.

3. A photomobile polymer (2) comprising a non-cross-linked resin (1) comprising at least one monomer and/or oligomer of liquid crystals having an azobenzene moiety in a concentration comprised between 6 and 10 mol %, doped with;
(a) ZnO nanoparticles in a concentration greater than or different from 6% and less than or equal to 7.5% by weight, the value of 6% not being included,
(b) silver nanoparticles in a concentration greater than 0.2% of the total,
(c) silver nanorods in a concentration greater than 0.2% of the total, or
(d) carbon black in a concentration of 0.03% to 2%, provided that when doped with carbon black in a concentration comprised between 0.03% and 2% the at least one monomer and/or oligomer of liquid crystals may not have an azobenzene moiety.

4. A handling device (300) for a photovoltaic panel, wherein the handling device (300) comprises:
(a) a frame (301) configured to accommodate at least one photovoltaic cell or panel and a load-bearing element (302) constrained with granted movement to said handling device (300) so as to allow movement from a first configuration (CF1) to a second configuration (CF2), and
(b) at least one flexible element (304) configured to move said frame (301) between said first configuration (CF1) and said second configuration (CF2),
wherein the at least one flexible element (304) is, or is connected to, a photomobile device (310) comprising a photomobile polymer layer (2) made according to claim 2 and is configured so as to be exposed to incident light radiation and to produce by means of its photoreaction deformations a displacement of said handling device (300) between said first configuration (CF1) and said second configuration (CF2).

5. The handling device (300) of claim 4, wherein said photomobile device (310) comprises a metal layer (312) laminated onto said photomobile polymer layer (2) on the opposite side to that on which said incident light radiation is incident.

6. The handling device (300) of claim 4, comprising a parabolic mirror (315) constrained in proximity to said photomobile device (310) and configured to collect said incident light radiation and concentrate it on said photomobile polymer layer (2).

7. The handling device (300) of 4, comprising three photomobile devices (310) configured to move said handling device (300) between said first configuration (CF1) and said second configuration (CF2) producing a complex rotation as a sum of several pure uniaxial rotations.

8. The handling device (300) of 4, wherein the at least one photomobile device (310) is constrained at one end to an installation surface (320) or to said load-bearing element (302).
